(19) United States
(12) Patent Application Publication
(10) Pub. No.: US 2026/0268853 A1
(43) Pub. Date: Sep. 10, 2026

(54) DISPLAY PANEL, DRIVING CIRCUIT, SHIFT REGISTER, AND DRIVING METHOD THEREFOR

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventor: Zhu WANG, Beijing (CN)

(73) Assignees: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(21) Appl. No.: 19/105,824

(22) PCT Filed: Aug. 29, 2024
(86) PCT No.: PCT/CN2024/115401

§ 371 Date: Feb. 24, 2025

(30) Foreign Application Priority Data
Sep. 28, 2023 (CN) 202311280233.7

(51) Int. Cl. G09G 3/3266; G09G 3/32; G09G 3/3233; G11C 19/28

(52) U.S. Cl. CPC G09G 3/3266; G09G 3/32; G09G 3/3233; G11C 19/28; G09G 2300/0426; G09G 2300/0842; G09G 2300/0861; G09G 2310/0286; G09G 2310/08; G09G 2320/0252

(57) ABSTRACT

A shift register includes: an input circuit, configured to transmit an input signal provided by an input terminal to a first input node; a voltage stabilization circuit, configured to transmit a first control signal to a first output node; a first control circuit, configured to transmit a second control signal to a second output node; a second control circuit, configured to control the first control signal and the second control signal; and an output circuit, configured to output a signal at a second voltage terminal or a third voltage terminal from an output terminal.

### CROSS-REFERENCE TO RELATED APPLICATION(S)

The present application claims priority to Chinese patent application No. 202311280233.7 filed on Sep. 28, 2023 with the title of “Display Panel, Driving Circuit, Shift Register, and Driving Method therefor”, the entire disclosure of which is incorporated herein by reference.

### TECHNICAL FIELD

The present disclosure relates to the field of display technology, and in particular to a display panel, a driving circuit, a shift register, and a driving method for the shift register.

### BACKGROUND

In a display panel using light-emitting diodes as light-emitting devices, its pixel circuit is usually scanning by using a signal output by a driving circuit, and the driving circuit includes multiple shift registers. When the output signal of the existing shift register is switched, there is a signal delay, which causes a delay in the picture.

It should be noted that the information described in the Background section is only used to enhance the understanding of the background of the present disclosure, and therefore may include information that does not constitute prior art known to those of ordinary skills in the art.

### SUMMARY

The present disclosure provides a display panel, a driving circuit, a shift register, and a driving method for the shift register, which can improve the signal delay problem.

According to an aspect of the present disclosure, a shift register is provided, including:
an input circuit, which is connected to the input terminal, the first clock signal terminal, and the first input node, and configured to transmit an input signal provided by the input terminal to the first input node in response to a first clock signal provided by the first clock signal terminal;
a voltage stabilization circuit, which is connected to the first voltage terminal, the first output node, and the first input node, and configured to transmit a first control signal to the first output node under the control of the voltage at the first input node;
a first control circuit, which is connected to the second voltage terminal, the second clock signal terminal, the third voltage terminal, the second output node, and the first input node, and is configured to transmit a second control signal to the second output node under the control of the second clock signal provided by the second clock signal terminal and the voltage at the first input node;
a second control circuit, which is connected to the third voltage terminal, the first input node, the first output node, and the second output node, and is configured to control the first control signal and the second control signal under the control of the voltage at the first input node and the second control signal; and
an output circuit, which is connected to the first output node, the second output node, the second voltage terminal, the third voltage terminal, and the output terminal, and is configured to output the signal at the second voltage terminal or the third voltage terminal from the output terminal under the control of the first control signal and the second control signal, where the voltage at the first voltage terminal is capable of enabling conduction between the second voltage terminal and the output terminal.

In an exemplary embodiment of the present disclosure, the first control circuit includes:
a first control subcircuit, which is connected to the second input node, the second voltage terminal, and the second clock signal terminal, and configured to be turned on or off under the control of the second clock signal;
a second control subcircuit, which is connected to the connection node, the first input node, and the third voltage terminal, and configured to be turned on or off under the control of the voltage at the first input node; and
a third control subcircuit, which is connected to the second input node and the connection node, and configured to be turned on or off under the control of the voltage at the third voltage terminal.

In an exemplary embodiment of the present disclosure, the first control subcircuit includes a first control transistor, the second control subcircuit includes a second control transistor, and the third control subcircuit includes a third control transistor and a first capacitor.

The first control transistor has the gate connected to the second clock signal terminal, the first terminal connected to the second voltage terminal, and the second terminal connected to the second input node.

The second control transistor has the gate connected to the first input node, the first terminal connected to the third voltage terminal, and the second terminal connected to the connection node.

The third control transistor has the gate connected to the connection node through the first capacitor, the first terminal connected to the connection node, and the second terminal connected to the second input node.

In an exemplary embodiment of the present disclosure, the voltage stabilization circuit includes a voltage stabilization transistor and a second capacitor.

The voltage stabilization transistor has the gate connected to the first input node and the second capacitor, the first terminal connected to the first voltage terminal, and the second terminal connected to the second capacitor and the first output node.

In an exemplary embodiment of the present disclosure, the second control circuit includes a fourth control subcircuit and a fifth control subcircuit.

The fourth control subcircuit is connected to the third voltage terminal, the first input node, and the second output node, and is configured to control the second control signal under the control of the voltage at the first input node.

The fifth control subcircuit is connected to the third voltage terminal, the first output node, and the second output node, and is configured to control the first control signal under the control of the voltage at the second output node.

In an exemplary embodiment of the present disclosure, the fourth control subcircuit includes a fourth control transistor, and the fifth control subcircuit includes a fifth control transistor.

The fourth control transistor has the gate connected to the first input node, the first terminal connected to the third voltage terminal, and the second terminal connected to the second output node.

The fifth control transistor has the gate connected to the second output node, the first terminal connected to the third voltage terminal, and the second terminal connected to the first output node.

In an exemplary embodiment of the present disclosure, the input circuit includes an input transistor. The input transistor has the gate connected to the first clock signal terminal, the first terminal connected to the input terminal, and the second terminal connected to the first input node.

The output circuit includes a first output transistor, a third capacitor, a second output transistor, and a fourth capacitor.

The first output transistor has the gate connected to the first output node, the first terminal connected to the second voltage terminal, the second terminal connected to the output terminal. The third capacitor connects the first output node and the second voltage terminal.

The second output transistor has the gate connected to the second output node, the first terminal connected to the third voltage terminal, and the second terminal connected to the output terminal. The fourth capacitor connects the second output node and the third voltage terminal.

In an exemplary embodiment of the present disclosure, the shift register further includes:
a first isolation circuit, connecting the first input node and the voltage stabilization circuit.

In an exemplary embodiment of the present disclosure, the shift register further includes:
a second isolation circuit, connecting the connection node and the second output node.

In an exemplary embodiment of the present disclosure, the first isolation circuit includes a first isolation transistor, and the second isolation circuit includes a second isolation transistor.

The first isolation transistor has the gate connected to the second voltage terminal, the first terminal connected to the first input node, and the second terminal connected to the voltage stabilization circuit.

The second isolation transistor has the gate connected to the second voltage terminal, the first terminal connected to the connection node, and the second terminal connected to the second output node.

According to an aspect of the present disclosure, a driving circuit is provided, including a plurality of cascaded shift registers, where the shift register includes the shift register described in any of the above embodiments.

According to an aspect of the present disclosure, a display panel is provided, the display panel including:
a driving backplane, including a plurality of pixel circuits and first driving circuits, where the pixel circuits are arranged in an array in the row direction and the column direction, the first driving circuit includes the driving circuit described in any of the above embodiments, and the output terminal of one of the first driving circuits is connected to at least one row of the pixel circuits; and
light-emitting devices, which are arranged in an array on a side of the driving backplane.

In an exemplary embodiment of the present disclosure, the pixel circuit includes a plurality of transistors, the number of the first driving circuits is two, and the display panel further includes a second driving circuit.

In the same pixel circuit, the gates of some transistors are connected to the output terminal of the first driving circuit, and the gates of some other transistors are connected to the output terminal of the second driving circuit. The two first driving circuits are connected to the gates of different transistors in the pixel circuit.

In an exemplary embodiment of the present disclosure, the pixel circuit includes a driving transistor, a writing transistor, a compensation transistor, a first reset transistor, a second reset transistor, a first light-emitting control transistor, a second light-emitting control transistor, and a storage capacitor. The first reset transistor and the compensation transistor are N-type metal oxide transistors. The driving transistor, the writing transistor, the second reset transistor, the first light-emitting control transistor, and the second light-emitting control transistor are P-type polysilicon transistors.

The first light-emitting control transistor has the first terminal used to receive a first power signal, and the second terminal connected to the first terminal of the driving transistor. The second terminal of the driving transistor is connected to the first terminal of the second light-emitting control transistor. The second terminal of the second light-emitting control transistor is connected to the light-emitting device. The compensation transistor has the first terminal connected to the second terminal of the driving transistor, and the second terminal connected to the gate of the driving transistor. The first reset transistor has the first terminal used to receive the first reset signal, and the second terminal connected to the second terminal of the compensation transistor. The second reset transistor has the first terminal used to receive the second reset signal, and the second terminal connected to the second terminal of the driving transistor. The writing transistor has the first terminal used to receive the data signal, and the second terminal connected to the first terminal of the driving transistor. The storage capacitor has the first plate connected to the gate of the driving transistor, and the second plate used to receive the first power signal.

The gate of the first reset transistor and the gate of the compensation transistor are connected to the output terminal of one of the first driving circuits. The gate of the first light-emitting control transistor and the gate of the second light-emitting control transistor are connected to the output terminal of the other of the first driving circuits. The gate of the writing transistor and the gate of the second reset transistor are connected to the output terminal of the second driving circuit.

According to an aspect of the present disclosure, a driving method for a shift register is provided. The shift register includes the shift register described in any of the above embodiments.

The driving method includes:
in the first stage, turning on the input circuit and turning off the first control circuit by the first clock signal and the second clock signal, turning on the voltage stabilization circuit, and enabling conduction between the second voltage terminal and the output terminal and disabling conduction between the third voltage terminal and the output terminal under the control of the first control signal;
in the second stage, turning off the input circuit and turning on the first control circuit by the first clock signal and the second clock signal, turning on the voltage stabilization circuit, and enabling conduction between the second voltage terminal and the output terminal and disabling conduction between the third voltage terminal and the output terminal under the control of the voltage at the first voltage terminal, the first control signal, and the second control signal;
in the third stage, turning on the input circuit by the first clock signal and the second clock signal, turning off the voltage stabilization circuit, and enabling conduction between the second voltage terminal and the output terminal and disabling conduction between the third voltage terminal and the output terminal under the control of the voltage at the first voltage terminal, the first control signal, and the second control signal; and
in the fourth stage, turning off the input circuit by the first clock signal and the second clock signal, turning off the voltage stabilization circuit, and disabling conduction between the second voltage terminal and the output terminal and enabling conduction between the third voltage terminal and the output terminal under the control of the voltage at the third voltage terminal, the first control signal, and the second control signal.

In an exemplary embodiment of the present disclosure, the absolute value of the voltage at the first voltage terminal is greater than the absolute value of the voltage at the second voltage terminal.

In an exemplary embodiment of the present disclosure, the absolute value of the difference between the absolute value of the voltage at the first voltage terminal and the absolute value of the voltage at the second voltage terminal is 3V.

In an exemplary embodiment of the present disclosure, the pulse width of the input signal is n times that of the first clock signal and the second clock signal, where n is a positive integer.

The display panel, the driving circuit, the shift register, and the driving method therefor of the present disclosure can enable or disable the conduction between the second voltage terminal and the output terminal under the control of the input signal, and at the same time, transmit the voltage at the first voltage terminal to the output circuit through the voltage stabilization circuit, so that the conduction between the second voltage terminal and the output terminal is stable. This helps to eliminate the step that occurs when the voltage at the third voltage terminal output at the output terminal changes to the voltage at the second voltage terminal. In addition, the above-mentioned step can be eliminated by externally connecting the first voltage terminal.

It should be understood that the above general description and the detailed description below are only exemplary and explanatory, and cannot limit the present disclosure.

### BRIEF DESCRIPTION OF THE DRAWINGS

The drawings herein are incorporated into the specification and constitute a part of the specification, showing embodiments consistent with the present disclosure, and are used together with the specification to explain the principles of the present disclosure. It is noted that the drawings described below are only some embodiments of the present disclosure. For those of ordinary skills in the art, other drawings may also be obtained based on these drawings without creative work.

FIG. 1 is a top view of a display panel according to an embodiment of the present disclosure.

FIG. 2 is a partial cross-sectional schematic diagram of a display panel according to an embodiment of the present disclosure.

FIG. 3 is a schematic diagram of a pixel circuit in a display panel according to an embodiment of the present disclosure.

FIG. 4 is a partial schematic diagram of a display panel according to an embodiment of the present disclosure.

FIG. 5 is a schematic diagram of a driving circuit in a display panel according to an embodiment of the present disclosure.

FIG. 6 is a schematic diagram of a shift register according to an embodiment of the present disclosure.

FIG. 7 is a schematic diagram of a shift register in the first stage according to an embodiment of the present disclosure.

FIG. 8 is a schematic diagram of a shift register in the second stage according to an embodiment of the present disclosure.

FIG. 9 is a schematic diagram of a shift register in the third stage according to an embodiment of the present disclosure.

FIG. 10 is a schematic diagram of a shift register in the fourth stage according to an embodiment of the present disclosure.

FIG. 11 is a timing diagram of a driving method for a shift register according to an embodiment of the present disclosure.

FIG. 12 is a timing diagram of a driving method for multiple shift registers according to an embodiment of the present disclosure.

FIG. 13 is a timing diagram of a driving method for a shift register according to another embodiment of the present disclosure.

FIG. 14 is a timing diagram of a driving method for multiple shift registers according to another embodiment of the present disclosure.

FIG. 15 is a timing diagram of a driving method for multiple shift registers according to another embodiment of the present disclosure.

### DETAILED DESCRIPTION OF THE EMBODIMENTS

The example embodiments will now be described more fully with reference to the accompanying drawings. However, the example embodiments may be implemented in a variety of forms and should not be construed as limited to the embodiments set forth herein. Rather, these embodiments are provided so that the present disclosure will be comprehensive and complete and the concept of the example embodiments will be fully conveyed to those skilled in the art. The same reference numerals in the drawings represent the same or similar structures, and their detailed descriptions will be omitted. In addition, the drawings are only schematic illustrations of the present disclosure and are not necessarily drawn to scale.

The terms “one”, “an”, “the”, “said”, and “at least one” are used to indicate the presence of one or more elements or components, etc. The terms “including” and “having” are used to indicate an open-ended inclusion, and mean that there may be additional elements or components, etc. in addition to the listed elements or components, etc. The terms “first”, “second”, and “third”, etc. are used only as markers and are not intended to limit the number of the associated objects.

The row direction X and the column direction Y in the present application are two intersecting directions, which may be perpendicular to each other. In the drawings of the present disclosure, the row direction X is horizontal and the column direction Y is vertical, but the present disclosure is not limited in this regard. It is known to those skilled in the art that if the display panel rotates, the actual orientation of the row direction X and the column direction Y may change.

The transistor in the present application includes a gate, a first terminal and a second terminal. The conduction between the first terminal and the second terminal may be enabled and disabled by controlling the voltage at the gate. The first terminal may be a source and the second terminal may be a drain. It is noted that the first terminal may also be a drain and the second terminal may also be a source. Specifically, if the signal is input via the first terminal, the first terminal is the source and the second terminal is the drain. If the signal is input via the second terminal, the second terminal is the source and the first terminal is the drain. That is, the source and the drain may be interchanged depending on the change of the input signal.

For a P-type transistor, when the gate receives a high-level signal, conduction between the first terminal and the second terminal is disabled; and when the gate receives a low-level signal, conduction between the first terminal and the second terminal is enabled. For an N-type transistor, when the gate thereof receives a high-level signal, conduction between the first terminal and the second terminal is enabled; and when the gate thereof receives a low-level signal, conduction between the first terminal and the second terminal is disabled.

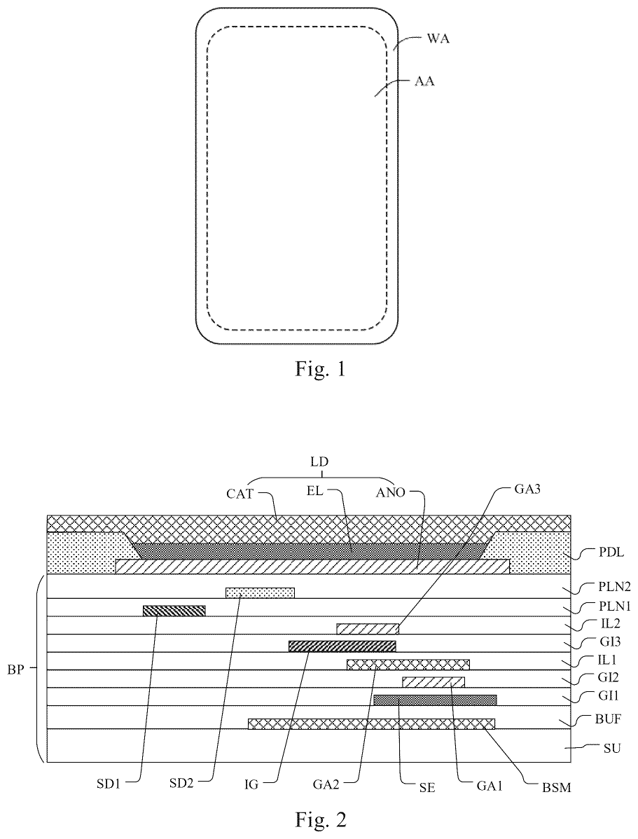

As shown in FIG. 1, the present disclosure provides a display panel, which may be divided into a plurality of areas, including a display area AA and a peripheral area WA located outside the display area AA. The peripheral area WA may be a continuous annular area surrounding the display area AA, or a discontinuous area surrounding the display area AA.

As shown in FIG. 2, the display panel may include a driving backplane BP and a plurality of light-emitting devices LD disposed on a side of the driving backplane BP. The light-emitting devices LD may be arranged in an array along the row direction X and the column direction Y, and located in the display area AA. The light-emitting device LD may be driven to emit light by a circuit in the driving backplane BP, thereby displaying an image.

As shown in FIG. 2, the light-emitting device LD may be an organic light-emitting diode (OLED) made of an organic light-emitting material, or may also be an light-emitting diode (LED) made of an inorganic light-emitting material, such as a micrometer light-emitting diode (Micro LED) and a sub-millimeter light-emitting diode (Mini LED). Alternatively, it may also be a device such as a quantum dot diode (QLED). The specific structure of the light-emitting device LD is not specifically limited here.

As shown in FIG. 2, the light-emitting device LD using OLED is taken as an example, which may include a first electrode ANO, a light-emitting layer EL, and a second electrode CAT stacked in sequence in a direction away from the driving backplane BP. By applying a first power signal to the first electrode ANO and a second power signal to the second electrode CAT, the light-emitting layer EL may be stimulated to emit light. The specific principle is not described in detail here. At the same time, in order to limit the range of the light-emitting device LD, a pixel definition layer PDL may be provided on the driving backplane BP. The pixel definition layer PDL and the first electrode ANO are located on the same surface of the driving backplane BP, and the pixel definition layer PDL may have a pixel opening exposing each first electrode ANO, so that the range of the light-emitting device LD may be limited by each pixel opening.

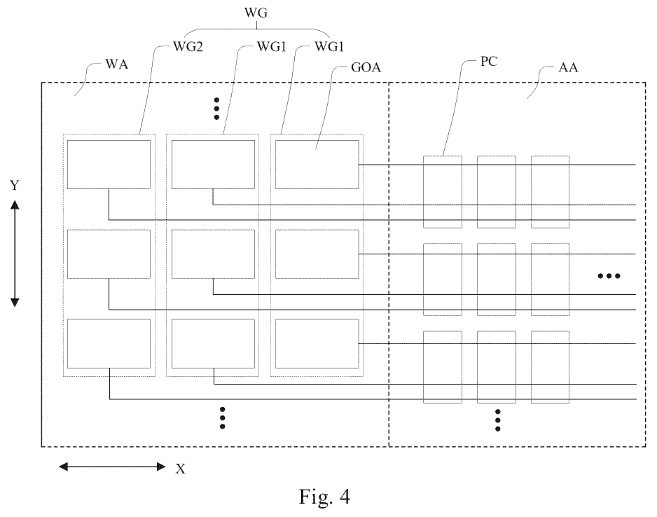

As shown in FIG. 4, the circuit of the driving backplane BP may include pixel circuits PC and driving circuits. The pixel circuits PC may be located in the display area AA and distributed in an array along the row direction X and the column direction Y. The pixel circuit PC may be connected to the first electrode ANO of a light-emitting device LD. It shall be noted that the same pixel circuit PC may also be connected to the first electrodes ANO of multiple light-emitting devices LD. The pixel circuit PC may include multiple transistors and capacitors, which may be pixel circuits such as 3T1C and 7T1C. nTmC indicates that a pixel circuit PC includes n transistors (indicated by the letter “T”) and m capacitors (indicated by the letter “C”).

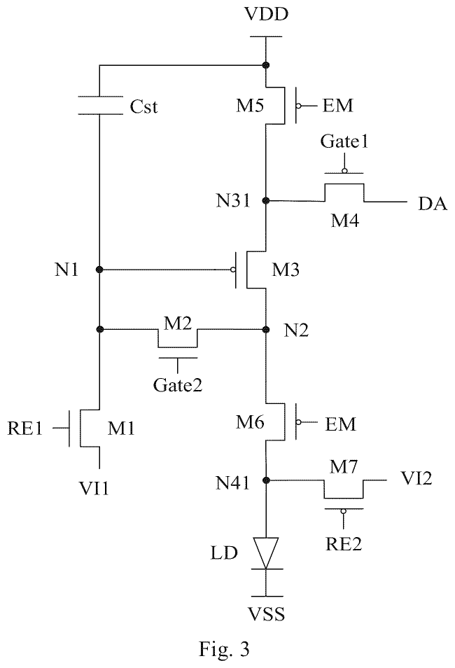

As shown in FIG. 3, the pixel circuit PC of 7T1C structure is taken as an example, which may include a first reset transistor M1, a compensation transistor M2, a driving transistor M3, a writing transistor M4, a first light-emitting control transistor M5, a second light-emitting control transistor M6, a second reset transistor M7, and a storage capacitor Cst. The conduction between the first terminal and the second terminal may be enabled or disabled by applying a scan signal to the gate of the transistor. The storage capacitor Cst may include the overlapping first and second plates.

As shown in FIG. 3, the first light-emitting control transistor M5 has the gate used to input a light-emitting scan signal EM, the first terminal used to input a first power signal VDD, and the second terminal connected to the first terminal of the driving transistor M3. The driving transistor M3 has the gate connected to the first node N1, and the second terminal connected to the second node N2 together with the first terminal of the second light-emitting control transistor M6. The second terminal of the second light-emitting control transistor M6 and the first electrode ANO of a light-emitting device LD are connected to the fourth node N41. The gate of the second light-emitting control transistor M6 is used to input the light-emitting scan signal EM. The second electrode CAT of the light-emitting device LD is used to input the second power signal VSS.

The first reset transistor M1 has the gate used to input the first reset scan signal RE1, the first terminal used to input the first reset signal VI1, and the second terminal connected to the gate of the driving transistor M3.

The writing transistor M4 has the gate used to input the writing scan signal Gate1, the first terminal used to input the data signal DA, and the second terminal connected to the third node N31 together with the first terminal of the driving transistor M3 and the second terminal of the first light-emitting control transistor M5.

The compensation transistor M2 has the gate used to input the compensation scan signal Gate2, the first terminal connected to the second node N2, and the second terminal connected to the first node N1, thereby connecting the second terminal and the gate of the driving transistor M3.

The second reset transistor M7 has the gate used to input the second reset scan signal RE2, the first terminal used to input the second reset signal VI2, and the second terminal connected to the fourth node N41, that is, connected to the first electrode ANO of the light-emitting device and the second terminal of the driving transistor M3.

The storage capacitor Cst has the first plate used to input the first power signal VDD, and the second plate connected to the first node N1, thereby connecting to the gate of the driving transistor M3.

The working principle of the pixel circuit of 7T1C is explained below.

In the first reset stage: the first reset transistor M1 is turned on by the first reset scan signal RE1, and the first reset signal VI1 is written to the first node N1. The gate of the driving transistor M3 and the second plate of the storage capacitor Cst can be reset.

In the writing stage: the writing transistor M4 and the compensation transistor M2 are turned on by the writing scan signal Gate1 and the compensation scan signal Gate2, and the other transistors are turned off; the data signal DA is written to the first node N1 through the third node N31 and the second node N2 until the potential reaches Vdata+vth, where Vdata is the voltage of the data signal DA, and Vth is the threshold voltage of the driving transistor M3. The writing scan signal Gate1 and the compensation scan signal Gate2 may be the same scan signal or two synchronized scan signals.

In the second reset phase: the compensation transistor M2, the writing transistor M4, the first light-emitting control transistor M5, and the second light-emitting control transistor M6 are turned off. At the same time, the second reset transistor M7 is turned on by the second reset scan signal RE2, and the second reset signal VI2 is transmitted to the first terminal of the second reset transistor M7 to reset the first electrode ANO of the light-emitting device LD.

In the light-emitting stage: the first light-emitting control transistor M5 and the second light-emitting control transistor M6 are turned on by the light-emitting scan signal EM, and other transistors are turned off; the driving transistor M3 is turned on under the action of the voltage Vdata+Vth stored in the storage capacitor Cst and the first power signal VDD, and the light-emitting device LD emits light under the action of the first power signal VDD and the second power signal VSS. Under the action of the storage capacitor Cst, the driving transistor M3 outputs a current, and the output current satisfies the following formula:

$$I = ( μ WCox / 2 L ) {( Vgs - Vth )}^{2} ;$$

where I is the output current of the driving transistor M3; μ is the carrier mobility; Cox is the gate capacitance per unit area, W is the channel width of the driving transistor M3, and L is the channel length of the driving transistor M3.

According to the above formula for the output current of the driving transistor M3, the gate voltage Vdata+Vth and the source voltage VDD of the driving transistor M3 in the pixel circuit of the present disclosure are substituted into the above formula to obtain: the output current I of the driving transistor M3=(μ WCox/2L)(Vdata+Vth−VDD−Vth)². It can be seen that the output current of the pixel circuit has nothing to do with the threshold voltage Vth of the driving transistor M3, but only with Vdata, thereby eliminating the influence of the threshold voltage of the driving transistor M3 on its output current. The output current can be controlled only by the voltage of the data signal DA, so as to control the brightness of the light-emitting device.

The transistors of the above-mentioned 7T1C pixel circuit may all be polysilicon transistors, that is, using the Low Temperature Polycrystalline Silicon (LTPS) process, or at least sone of the transistors may be metal oxide transistors, for example, using the Low Temperature Polycrystalline Oxide (LTPO) process. That is, the first reset transistor M1 and the compensation transistor M2 are metal oxide transistors, and the other transistors are polysilicon transistors. The metal oxide transistor can reduce leakage of electricity. If a metal oxide transistor is used, it is an N-type transistor, and if a polysilicon transistor is used, it may be a P-type transistor.

As shown in FIG. 4, the driving circuit WG may be arranged in the peripheral area WA, and may be connected to the light-emitting device LD through the pixel circuit PC, and may apply a first power signal to the first electrode ANO of the light-emitting device LD. The number of the driving circuits WG may be multiple, and may be divided into multiple categories, and may be used to scan the transistors in the pixel circuit PC. The driving circuits WG may also be arranged in whole or in part in the display area AA, as long as it can scan the pixel circuit PC. Taking the above-mentioned 7T1C pixel circuit as an example, the driving circuit WG may be divided into two categories. One of the two categories is a gate driving circuit, which is used to scan some transistors in the pixel circuit PC (for example, the first reset transistor M1, the second reset transistor M7, the compensation transistor M2, and the writing transistor M4), that is, to output the first reset scan signal RE1, the second reset scan signal RE2, the compensation scan signal Gate2, and the writing scan signal Gate1 to the gates of the first reset transistor M1, the second reset transistor M7, the compensation transistor M2, and the writing transistor M4. The other category is a light-emitting driving circuit, which may be used to scan the first light-emitting control transistor M5 and the second light-emitting control transistor M6, that is, to output a scan signal (light-emitting scan signal EM) to the gates of the first light-emitting control transistor M5 and the second light-emitting control transistor M6. The first reset scan signal RE1, the second reset scan signal RE2, the compensation scan signal Gate2, the writing scan signal Gate1, and the light-emitting scan signal EM are all scan signals output by the driving circuit WG. The signals output by the above-mentioned gate driving circuit and the light-emitting driving circuit can enable or disable the conduction of the transistor(s) in the pixel circuit PC, that is, realizing the scanning of the pixel circuit PC.

The peripheral area WA of the display panel may also be provided with a power bus connected to the second electrode CAT of the light-emitting device LD, and a second power signal is applied to the second electrode CAT. The current passing through the light-emitting device LD may be controlled through the pixel circuit PC, thereby controlling the brightness of the light-emitting device LD.

A driving circuit WG may include multiple cascaded shift registers GOA. That is, the output terminal of the upper-stage shift register GOA is connected to the input terminal of the lower-stage shift register GOA, so that the output signal of the upper-stage shift register GOA is used as the input signal of the lower-stage shift register GOA. At the same time, the input signal of the first-stage shift register GOA may be a trigger signal. In addition, in some embodiments, the first-stage shift register GOA may be a dummy register, the output terminal of which is not connected to the pixel circuit PC, but only serves as an input signal of the next-stage shift register GOA. Any shift register GOA may include multiple transistors and capacitors, which may be structures such as 8T2C, 10T3C, etc., and are not specifically limited here.

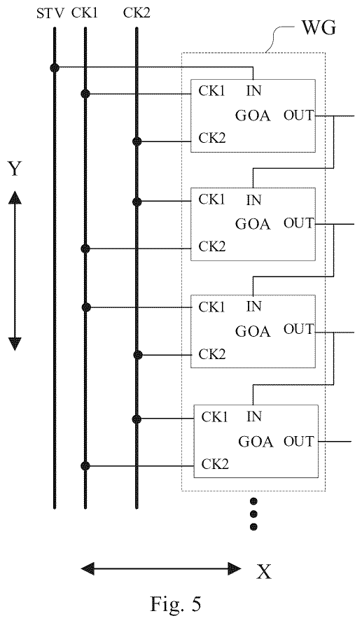

As shown in FIG. 5, the output signal at the output terminal OUT of the shift register GOA is the above-mentioned scan signal, and the gates of some transistors of a row of pixel circuits PC may be connected to the output terminal of the shift register GOA in a stage. It shall be noted that the shift register GOA in a stage may be connected to multiple rows of pixel circuits PC, and scan multiple rows of pixel circuits PC at the same time. But, the output signal of the same shift register GOA may have different effects in different rows of pixel circuits PC. For example, when the pixel circuit PC in the i-th row is in the writing stage, the pixel circuit PC in the i+1th row is in the first reset stage, where i is a positive integer.

When controlling the on and off state of the transistor of the pixel circuit PC, the output signal at the output terminal of the shift register GOA, i.e., the scan signal, needs to be switched between a high level and a low level. However, since response is required for the on and off state of the transistor, there is a step at the rising or falling edge of the scan signal, which causes a delay in the scanning of the pixel circuit PC, and thus causes a delay in the switching. For example, the first light-emitting control transistor M5 and the second light-emitting control transistor M6 are P-type transistors. When the light-emitting scan signal EM switches from a high level to a low level, there is a step at the falling edge of the light-emitting scan signal EM, which causes the first light-emitting control transistor M5 and the second light-emitting control transistor M6 to be turned on with delay, and the light-emitting device LD emits light with delay.

In order to improve this problem, a large number of transistors and capacitors can be added to the shift register GOA, and the signal can be stabilized inside the shift register by using the principle of bootstrapping, etc., thereby reducing the above-mentioned step. However, this will make the shift register have more transistors and capacitors and a more complex structure. Therefore, the present inventor(s) proposes that the output signal of the shift register GOA can be controlled by an external voltage to reduce or eliminate the above-mentioned step, thereby improving the delay. The following is a detailed description.

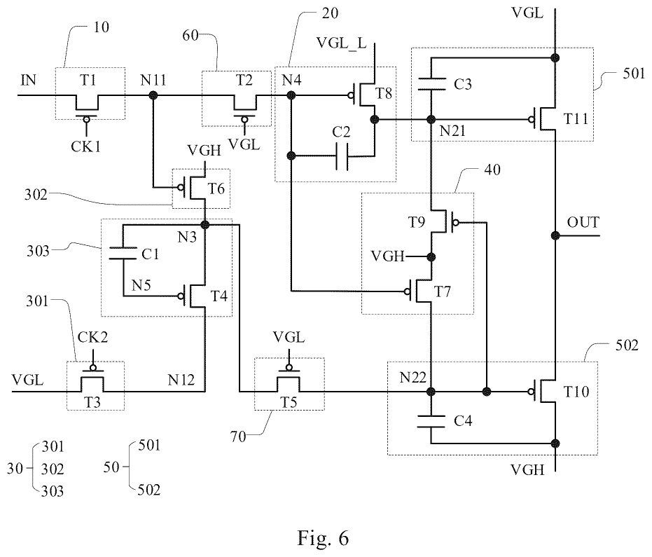

As shown in FIG. 6, the shift register GOA may include an input circuit 10, a voltage stabilization circuit 20, a first control circuit 30, a second control circuit 40, and an output circuit 50.

The input circuit 10 is connected to the input terminal IN, the first clock signal terminal CK1, and the first input node N11, and is configured to transmit the input signal provided by the input terminal IN to the first input node N11 in response to the first clock signal provided by the first clock signal terminal CK1.

The voltage stabilization circuit 20 is connected to the first voltage terminal VGL_L, the first output node N21, and the first input node N11, and is configured to transmit the first control signal to the first output node N21 under the control of the voltage at the first input node N11.

The first control circuit 30 is connected to the second voltage terminal VGL, the second clock signal terminal CK2, the third voltage terminal VGH, the second output node N22, and the first input node N11, and is configured to transmit the second control signal to the second output node N22 under the control of the second clock signal provided by the second clock signal terminal CK2 and the voltage at the first input node N11.

The second control circuit 40 is connected to the third voltage terminal VGH, the first input node N11, the first output node N21, and the second output node N22, and is configured to control the first control signal and the second control signal under the control of the voltage at the first input node N11 and the second control signal.

The output circuit 50 is connected to the first output node N21, the second output node N22, the second voltage terminal VGL, the third voltage terminal VGH, and the output terminal OUT, and is configured to output the signal at the second voltage terminal VGL or the third voltage terminal VGH from the output terminal OUT under the control of the first control signal and the second control signal. The voltage at the first voltage terminal VGL_L is capable of disabling conduction between the second voltage terminal VGL and the output terminal OUT.

The following is an explanation about the effect of the shift register GOA in combination with its working principle.

As shown in FIG. 6, in the first stage, by using the first clock signal and the second clock signal, the input circuit 10 can be turned on, the first control circuit 30 can be turned off, and the input signal can be transmitted to the first input node N11. The input signal can turn on the voltage stabilization circuit 20, and the first control signal is transmitted to the first output node N21. The voltage stabilization circuit 20 can control the first control signal under the control of the voltage at the first voltage terminal VGL_L. Under the control of the first control signal, conduction between the second voltage terminal VGL and the output terminal OUT can be enabled, and conduction between the third voltage terminal VGH and the output terminal OUT can be disabled. At this time, the voltage of the output signal at the output terminal OUT is the voltage provided by the second voltage terminal VGL.

In the second stage, by using the first clock signal and the second clock signal, the input circuit 10 is turned off, the voltage stabilization circuit 20 remains turned on, the first control circuit 30 is turned on, and the second voltage terminal VGL transmits the second control signal to the second output node N22 through the first control circuit 30. Under the control of the voltage at the first voltage terminal VGL_L, the first control signal, and the second control signal, conduction between the second voltage terminal VGL and the output terminal OUT is enabled, and conduction between the third voltage terminal VGH and the output terminal OUT is disabled. At this time, the voltage of the output signal at the output terminal OUT is the voltage provided by the second voltage terminal VGL.

In the third stage, by using the first clock signal and the second clock signal, the input circuit 10 is turned on, the voltage stabilization circuit 20 is turned off, and under the control of the voltage at the first voltage terminal VGL_L, the first control signal, and the second control signal, conduction between the second voltage terminal VGL and the output terminal OUT is enabled, and conduction between the third voltage terminal VGH and the output terminal OUT is disabled. At this time, the voltage of the output signal at the output terminal OUT is the voltage at the second voltage terminal VGL.

In the fourth stage, by using the first clock signal and the second clock signal, the input circuit 10 is turned off, the voltage stabilization circuit 20 is turned off, and under the control of the voltage at the third voltage terminal VGH, the first control signal, and the second control signal, conduction between the second voltage terminal VGL and the output terminal OUT is disabled, and conduction between the third voltage terminal VGH and the output terminal OUT is enabled. At this time, the voltage of the output signal at the output terminal OUT is the voltage at the third voltage terminal VGH.

The above four stages may be a cycle. That is, the next stage after the fourth stages is the first stage in another cycle. The first voltage terminal VGL_L and the second voltage terminal VGL may be used to provide a low-level signal, and the third voltage terminal VGH may be used to provide a high-level signal. From the above working principle, it can be seen that based on the first input signal and the first control signal, before the low-level signal is switched to the high-level signal, conduction between the second voltage terminal VGL and the output terminal OUT may be continuously enabled by the voltage at the first voltage terminal VGL_L. When the high-level signal is switched to the low-level signal, conduction between the second voltage terminal VGL and the output terminal OUT can be enabled, thereby increasing the switching speed of the signal and eliminating the step at the rising or falling edge of the output signal. Thereby, the delay is improved by the first voltage terminal VGL_L and the voltage stabilization circuit 20 without setting a bootstrap circuit, which is conducive to simplifying the structure of the shift register GOA.

The following is an exemplary description about a partial circuit of the shift register GOA.

In some embodiments of the present disclosure, the first control circuit 30 may transmit a second control signal to the second output node N22 or shut down under the control of the voltage at the first input node N11, the second voltage terminal VGL, and the third voltage terminal VGH. The first control circuit 30 may include a first control subcircuit 301, a second control subcircuit 302, and a third control subcircuit 303.

The first control subcircuit 301 may be connected to the second input node N12, the second voltage terminal VGL, and the second clock signal terminal CK2, and is configured to be turned on or off under the control of the second clock signal.

The second control subcircuit 302 may be connected to the connection node N3, the first input node N11, and the third voltage terminal VGH, and is configured to be turned on or off under the control of the voltage at the first input node N11.

The third control subcircuit 303 may be connected to the second input node N12 and the connection node N3, and is configured to be turned on or off under the control of the voltage at the third voltage terminal VGH.

As shown in FIG. 6, in some embodiments of the present disclosure, the second control circuit 40 includes a fourth control subcircuit and a fifth control subcircuit.

The fourth control subcircuit is connected to the third voltage terminal VGH, the first input node N11, and the second output node N22, and is configured to control the second control signal under the control of the voltage at the first input node N11.

The fifth control subcircuit is connected to the third voltage terminal VGH, the first output node N21, and the second output node N22, and is configured to control the first control signal under the control of the voltage at the second output node N22.

In some embodiments of the present disclosure, the output circuit 50 may include a first output subcircuit 501 and a second output subcircuit 502.

The first output subcircuit 501 may be connected to the first output node N21, the second voltage terminal VGL, and the output terminal OUT, and may enable or disable conduction between the second voltage terminal VGL and the output terminal OUT under the control of the first control signal. The second output subcircuit 502 may be connected to the second output node N22, the third voltage terminal VGH, and the output terminal OUT, and may enable or disable conduction between the third voltage terminal VGH and the output terminal OUT under the control of the second control signal.

As shown in FIG. 6, in some embodiments of the present disclosure, the shift register GOA of the present disclosure may also include a first isolation circuit 60, which may be connected to the first input node N11, the voltage stabilization circuit 20, and the second voltage terminal VGL. The first isolation circuit 60 may be turned on under the action of the voltage at the second voltage terminal VGL, and may prevent the first output node N21 from leaking electricity to the first input node N11, thereby playing an isolation role.

Optionally, the shift register GOA may also include a second isolation circuit 70, which may be connected to the connection node N3, the second output node N22, and the second voltage terminal VGL. The second isolation circuit 70 may be turned on under the action of the voltage at the second voltage terminal VGL, and may prevent the second output node N22 from leaking electricity to the second input node N12, thereby playing an isolation role.

The specific structure of the shift register GOA is exemplarily described below.

As shown in FIG. 6, in some embodiments of the present disclosure, the input circuit 10 includes an input transistor T1. The first control subcircuit 301 includes a first control transistor T3, the second control subcircuit 30232 includes a second control transistor T6, and the third control subcircuit 303 includes a third control transistor T4 and a first capacitor C1. The voltage stabilization circuit 20 includes a voltage stabilization transistor T8 and a second capacitor C2. The fourth control subcircuit includes a fourth control transistor T7. The fifth control subcircuit includes a fifth control transistor T9. The first output subcircuit 501 may include a first output transistor T11 and a third capacitor C3. The second output subcircuit 502 includes a second output transistor T10 and a fourth capacitor C4. The first isolation circuit 60 includes a first isolation transistor T2, and the second isolation circuit 70 includes a second isolation transistor T5.

The input transistor T1 has the gate connected to the first clock signal terminal CK1, the first terminal connected to the input terminal IN, and the second terminal connected to the first input node N11.

The first control transistor T3 has the gate connected to the second clock signal terminal CK2, the first terminal connected to the second voltage terminal VGL, and the second terminal connected to the second input node N12. The second control transistor T6 has the gate connected to the first input node N11, the first terminal connected to the third voltage terminal VGH, and the second terminal connected to the connection node N3. The gate of the third control transistor T4 is connected to the middle node N5 together with one plate of the first capacitor C1, the other plate of the first capacitor C1 is connected to the first terminal of the third control transistor T4 and the connection node N3, and the second terminal of the third control transistor T4 is connected to the second input node N12.

The voltage stabilization transistor T8 has the gate connected to the first input node N11 and one plate of the second capacitor C2, the first terminal connected to the first voltage terminal VGL_L, and the second terminal connected to the other plate of the second capacitor C2 and the first output node N21. For example, the gate of the voltage stabilization transistor T8 may be connected to the transition node N4, and the transition node N4 may be connected to the first input node N11 through the first isolation transistor T2, so as to connect the gate of the voltage stabilization transistor T8 to the first input node N11. The first isolation transistor T2 has the gate connected to the second voltage terminal VGL, the first terminal connected to the first input node N11, and the second terminal connected to the transition node N4.

The fourth control transistor T7 has the gate connected to the first input node N11. For example, the gate is connected to the transition node N4. The fourth control transistor T7 has the first terminal connected to the third voltage terminal VGH, and the second terminal connected to the second output node N22. The fifth control transistor T9 has the gate connected to the second output node N22, the first terminal connected to the third voltage terminal VGH, and the second terminal connected to the first output node N21.

The first output transistor T11 has the gate connected to the first output node N21, the first terminal connected to the second voltage terminal VGL, and the second terminal connected to the output terminal OUT. One plate of the third capacitor C3 is connected to the first output node N21, and the other plate of the third capacitor C3 is connected to the second voltage terminal VGL.

The second output transistor T10 has the gate connected to the second output node N22, the first terminal connected to the third voltage terminal VGH, the second terminal connected to the output terminal OUT. One plate of the fourth capacitor C4 is connected to the second output node N22, and the other plate of the fourth capacitor C4 is connected to the third voltage terminal VGH.

The second isolation transistor T5 has the gate connected to the second voltage terminal VGL, the first terminal connected to the connection node N3, and the second terminal connected to the second output node N22. The connection node N3 is connected to the second output node N22 through the second isolation transistor T5.

The following takes the shift register GOA as an example where all the transistors are P-type transistors, and combines the shift register GOA in the above embodiment(s) to describe the driving method therefor in detail.

The voltage output by the first voltage terminal VGL_L is the first voltage, and the voltage output by the second voltage terminal VGL is the second voltage. The first voltage and the second voltage are both low-level voltages, and the absolute value of the first voltage is greater than the absolute value of the second voltage. For example, the difference between the absolute value of the first voltage and the absolute value of the second voltage is 3V. The voltage output by the third voltage terminal VGH is the third voltage, and the third voltage is a high-level voltage.

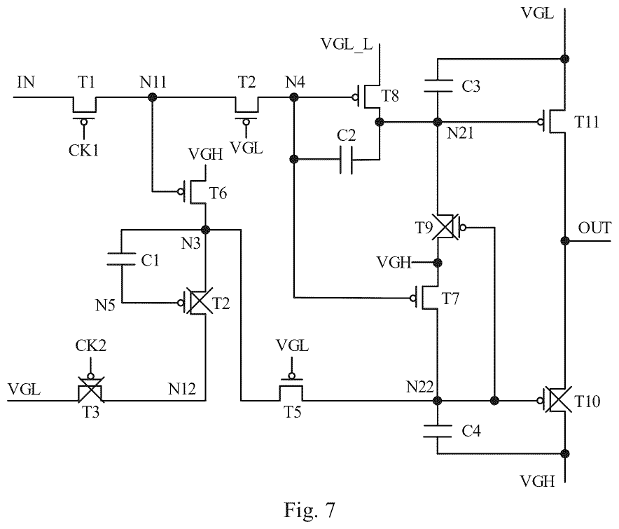

As shown in FIGS. 7, 11, and 13, in the first stage, the first clock signal is low level and the input signal is low level. The input transistor T1 is turned on, the first isolation transistor T2 is always on, and the input signal is transmitted to the first input node N11 and the transition node N4, so that the second control transistor T6, the fourth control transistor T7, and the voltage stabilization transistor T8 are turned on. The third voltage terminal VGH may charge the first capacitor C1 through the second control transistor T6 and the connection node N3. At this time, the third control transistor T4 does not meet the conduction condition and is in the off state. The first voltage terminal VGL_L provides the first voltage to the first output node N21 through the voltage stabilization transistor T8, so that the voltage of the output signal at the output terminal OUT of the first output transistor T11 is the first voltage. At the same time, the second clock signal is high level, so that the first control transistor T3 is turned off, and the third control transistor T4 is turned off. The third voltage terminal VGH may transmit the third voltage to the second output node N22 through the fourth control transistor T7, so that the fifth control transistor T9 and the second output transistor T10 are turned off.

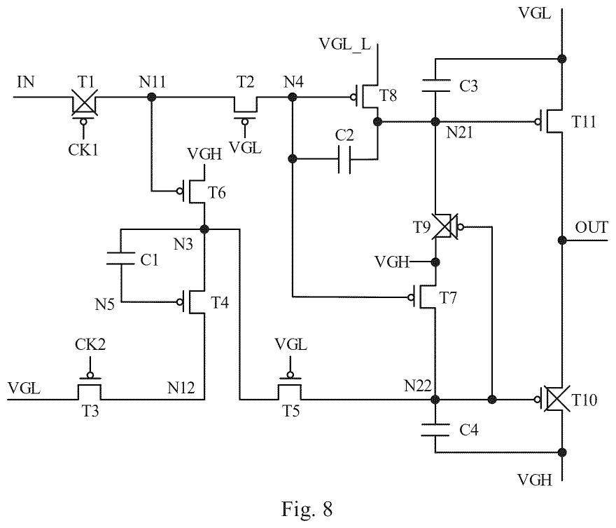

As shown in FIGS. 8, 11, and 13, in the second stage, the first clock signal becomes high level, and the input signal is still low level. The input transistor T1 is turned off. Under the action of the second capacitor C2, the second control transistor T6, the voltage stabilization transistor T8, and the fourth control transistor T7 are continuously turned on. Under the action of the first voltage terminal VGL_L and the third capacitor C3, the first output transistor T11 is continuously turned on. At this time, the voltage of the output signal at the output terminal OUT is still the second voltage at the second voltage terminal VGL. The third voltage terminal VGH continuously controls the voltage at the second output node N22, so that the fifth control transistor T9 and the second output transistor T10 are turned off. At the same time, the second clock signal becomes low level, and the first control transistor T3 is turned on. Under the continuous action of the third voltage terminal VGH, the voltage difference between the connection node N3 and the third control transistor T4 reaches the conduction condition. That is, the gate-source voltage difference is greater than the threshold voltage of the third control transistor T4. The third control transistor T4 is turned on. The second voltage at the second voltage terminal VGL is transmitted to the second output node N22 through the continuously-on second isolation transistor T5. The voltage at the second output node N22 is pulled down, but the fifth control transistor T9 and the second output transistor T10 may still be kept off.

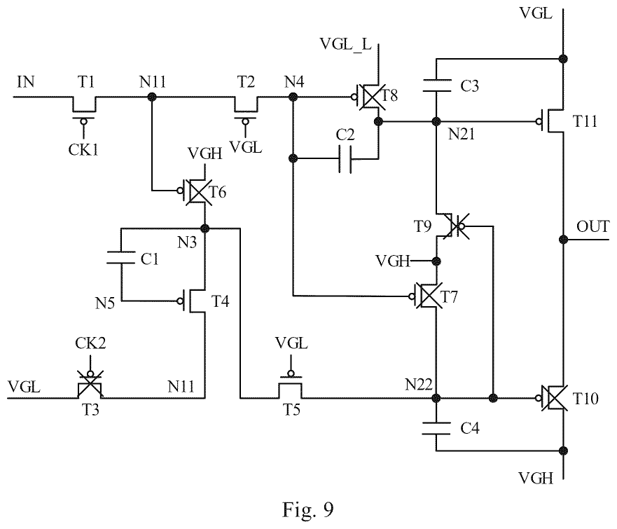

As shown in FIGS. 9, 11, and 13, in the third stage, the first clock signal becomes low level, the input signal becomes high level, the input transistor T1 is turned on, the first isolation transistor T2 is always on, and the input signal turns off the second control transistor T6, the fourth control transistor T7, and the voltage stabilization transistor T8. Under the coupling effect of the second capacitor C2, the voltage at the first output node N21 increases due to the high level at the transition node N4, and gradually turns off the first output transistor T11, but the first output transistor T11 may still remain turned on for a period of time. Combined with the effect of the third capacitor C3, the voltage of the output signal at the output terminal OUT may still maintain a low-level second voltage for a period of time. Under the effect of the first capacitor C1, the third control transistor T4 is continuously turned on. At the same time, the second clock signal is high level, which turns off the first control transistor T3. Under the effect of the fourth capacitor C4, the fifth control transistor T9 and the second output transistor T10 remain turned off.

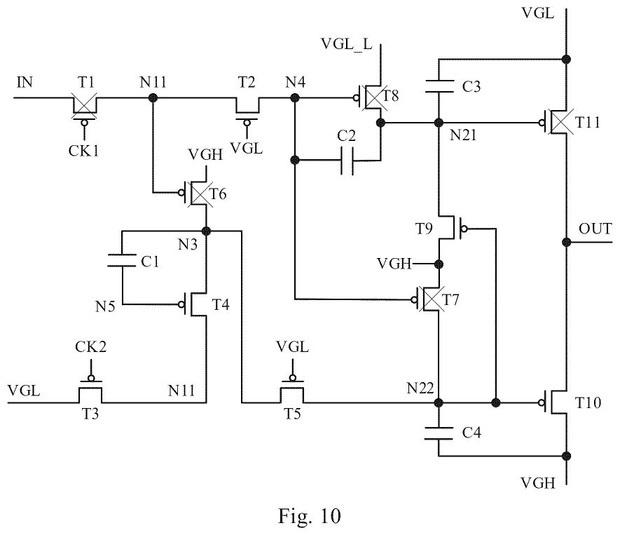

As shown in FIGS. 10, 11, and 13, in the fourth stage, the first clock signal becomes high level, the input signal becomes low level, the input transistor T1 is turned off, and the first isolation transistor T2 is always on. Under the action of the second capacitor C2, the second control transistor T6, the fourth control transistor T7, and the voltage stabilization transistor T8 are turned off. Under the action of the first capacitor C1, the third control transistor T4 is continuously turned on. At the same time, the second clock signal is low level, so that the first control transistor T3 is turned on, the second voltage is written into the second output node N22, the fifth control transistor T9 and the second output transistor T10 are turned on, and the third voltage terminal VGH may write the third voltage to the first output node N21 through the fifth control transistor T9, thereby turning off the first output transistor T11. The output signal at the output terminal OUT is the high-level third voltage.

Based on the above driving method, the output signal is switched from the low-level second voltage to the high-level third voltage. In this process, under the action of the first voltage terminal VGL_L, the voltage at the first output node N21 can be stabilized to ensure that the output terminal OUT outputs the signal stably. In particular, under the control of the voltage at the first voltage terminal VGL_L, the step existing on the falling edge when the high and low levels are switched can be eliminated. Compared with adding a large number of transistors and capacitors to use the bootstrap principle, the step on the falling edge can be eliminated by controlling the signal inside the shift register. The implementation of the above-mentioned first voltage at the external first voltage terminal VGL_L only requires the voltage stabilization transistor T8 and the second capacitor C2, and the structure is simpler.

It should be noted that although the steps of the driving method in the present disclosure are described in a specific order in the accompanying drawings, this does not require or imply that these steps must be performed in this specific order, or that all the steps shown must be performed to achieve the desired result. In addition or alternatively, some steps may be omitted, multiple steps may be combined into one step, and/or one step may be decomposed into multiple steps.

As shown in FIG. 5, based on the above-mentioned driving method, by adjusting the pulse width of the input signal, that is, the width of the high-level input signal, the duration of the output signal and the pulse width of the input signal can be controlled. For a driving circuit WG, its multiple shift registers GOA are cascaded. Thus, the input signal of the first-stage shift register GOA, that is, the pulse width of the trigger signal STV, may be used to control the pulse width of the output signal of each shift register GOA. At the same time, the pulse width of the input signal is n times that of the first clock signal and the second clock signal, where n is a positive integer. For example, n is 1, 2, 3, etc.

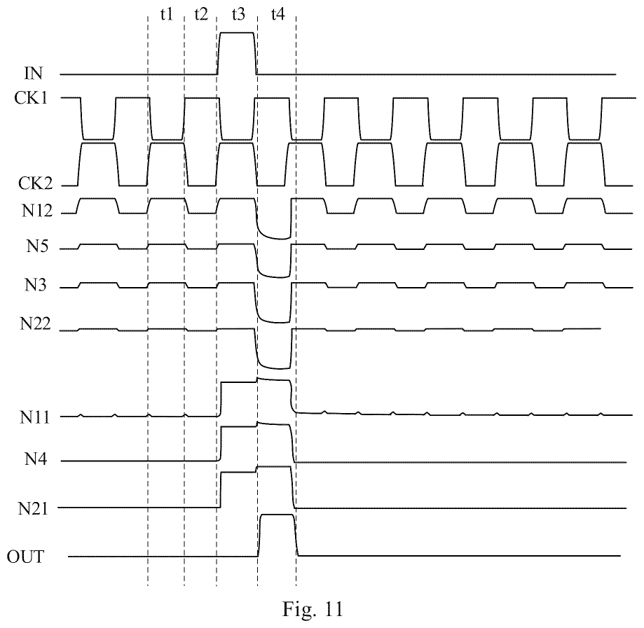

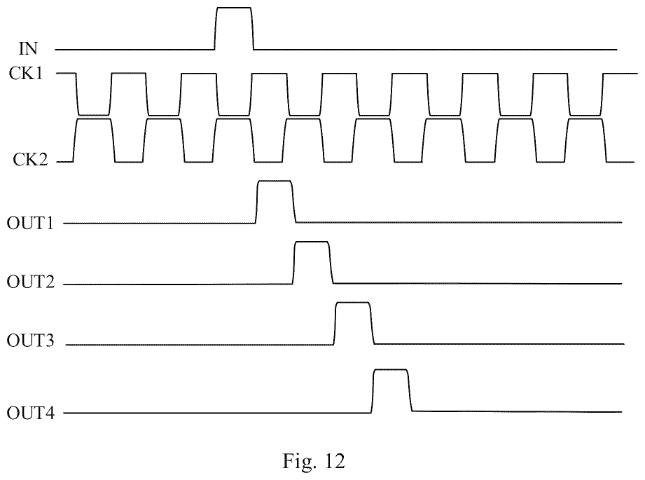

As shown in FIGS. 11 and 12, the pulse width of the trigger signal STV is the same as the pulse width of the first clock signal (the signal at the first clock signal terminal CK1) and the second clock signal (the signal at the second clock signal terminal CK2), that is, n=1. FIG. 12 shows the timing diagram of the output signal at the output terminal OUT of the four cascaded shift registers GOA, that is, the timing diagram of the output signal at the first output terminal OUT1 to the fourth output terminal OUT4.

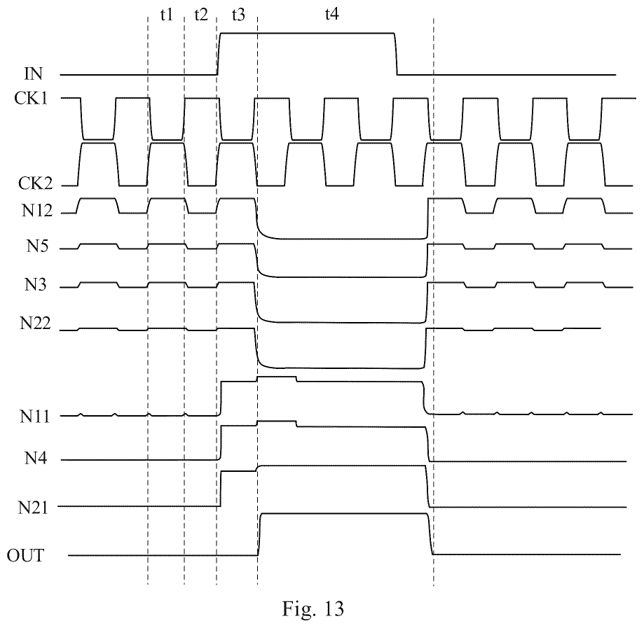

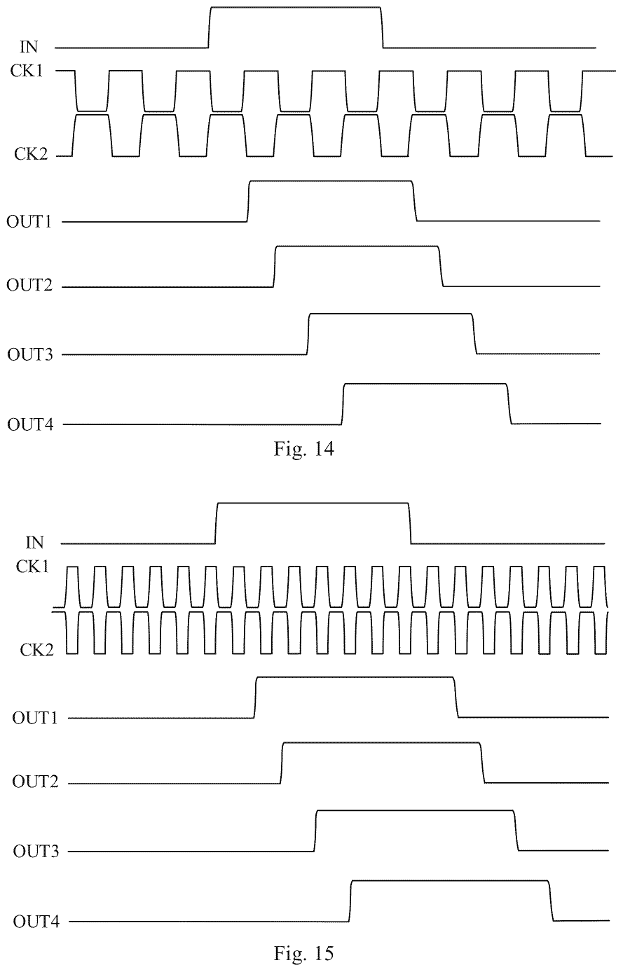

As shown in FIGS. 13 and 14, the pulse width of the trigger signal STV is 5 times the pulse width of the first clock signal and the second clock signal, that is, n=5. FIG. 14 shows the timing diagram of the output signal at the output terminal OUT of the four cascaded shift registers GOA, that is, the timing diagram of the output signal at the first output terminal OUT1 to the fourth output terminal OUT4.

As shown in FIG. 15, the pulse width of the trigger signal STV is 14 times the pulse width of the first clock signal and the second clock signal, that is, n=14. FIG. 15 shows the timing diagram of the output signal at the output terminal OUT of the four cascaded shift registers GOA, that is, the timing diagram of the output signal at the first output terminal OUT1 to the fourth output terminal OUT4.

The above-mentioned shift register GOA may be used not only for gate driving circuits, but also for light-emitting driving circuits. The above-mentioned shift register GOA may scan not only P-type transistors but also N-type transistors. In the same pixel circuit, the gates of some transistors are connected to the output terminal OUT of the first driving circuit, and the gates of some other transistors are connected to the output terminal OUT of the second driving circuit. The two first driving circuits are connected to the gates of different transistors in the pixel circuit.

In some embodiments of the present disclosure, for the 7T1C pixel circuit using the LTPO process mentioned above, the driving circuit WG may include two identical first driving circuits WG1 and one second driving circuit WG2. One of the first driving circuits WG1 is a gate driving circuit, which may be used to scan the first reset transistor M1 and the compensation transistor M2, that is, the output terminal OUT of which is connected to the gates of the first reset transistor M1 and the compensation transistor M2. The other first driving circuit WG1 is a light-emitting driving circuit, which may be used to scan the first light-emitting control transistor M5 and the second light-emitting control transistor M6, that is, the output terminal OUT of which is connected to the gates of the first light-emitting control transistor M5 and the second light-emitting control transistor M6.

The second driving circuit WG2 is different from the first driving circuit WG1. That is, the shift register GOA of the second driving circuit WG2 is different from the shift register GOA of the first driving circuit WG1. The second driving circuit WG2 is used to scan the writing transistor M4 and the second reset transistor M7, that is, the output terminal OUT of which is connected to the gates of the writing transistor M4 and the second reset transistor M7.

It should be noted that in the same pixel circuit, the shift register GOA connected to the transistors connected to the same driving circuit WG may not be of the same stage, and the output terminal OUT of the same shift register GOA may be connected to the transistors of multiple rows of pixel circuits.

In addition, the number of the first voltage terminal VGL_L, the second voltage terminal VGL, and the third voltage terminal VGH in the present application is not limited to one, as long as the voltage is the same. For example, multiple transistors are connected to the second voltage terminal VGL, which may be multiple transistors connected to the same voltage terminal, or respectively connected to multiple voltage terminals that can output the second voltage.

The following is an exemplary description about the film layer of the driving backplane.

As shown in FIG. 2, the driving backplane BP may include a substrate SU, as well as a light shielding layer BSM, a first semiconductor layer SE, a first gate layer GA1, a second gate layer GA2, a second semiconductor layer IG, a third gate layer GA3, a first source and drain layer SD1, and a second source and drain layer SD2, which are sequentially arranged in a direction away from the substrate SU.

The light shielding layer BSM is arranged on one side of the substrate SU, and the material thereof may be metal or other conductive and light shielding materials. The light shielding layer BSM may at least overlap with the driving transistor M3 to avoid the influence of the bottom signal and light on the driving transistor M3.

As shown in FIG. 2, the first semiconductor layer SE is arranged on the side of the light shielding layer BSM away from the substrate SU. The material of the first semiconductor layer SE may be polysilicon, which may include the active parts of the driving transistor M3, the writing transistor M4, the first light-emitting control transistor M5, the second light-emitting control transistor M6, as well as the active parts of each transistor of the shift register GOA.

As shown in FIG. 2, the first gate layer GA1 is arranged on the side of the first semiconductor layer SE away from the substrate SU. The first gate layer GA1 may include a storage capacitor Cst, one plate of the first capacitor C1 to the fourth capacitor C4, and the gates of some transistors.

As shown in FIG. 2, the second gate layer GA2 is arranged on the side of the first gate layer GA1 away from the substrate SU, and includes the storage capacitor Cst and another plate of the first capacitor C1 to the fourth capacitor C4.

As shown in FIG. 2, the second semiconductor layer IG may be disposed on the side of the second gate layer GA2 away from the substrate SU, and the material thereof may be a metal oxide such as IGZO. The second semiconductor layer IG may include the active parts of the first reset transistor M1 and the compensation transistor M2.

As shown in FIG. 2, the third gate layer GA3 may be disposed on the side of the second semiconductor layer IG away from the substrate SU, and overlap with the second semiconductor layer IG. The third gate layer GA3 may include the gates of the first reset transistor M1 and the compensation transistor M2.

As shown in FIG. 2, the first source and drain layer SD1 may be disposed on the side of the third gate layer GA3 away from the substrate SU, and may connect some transistors and capacitors.

As shown in FIG. 2, the second source and drain layer SD2 is disposed on the side of the first source and drain layer SD1 away from the substrate SU.

In addition, as shown in FIG. 2, the driving backplane BP may also include a buffer layer BUF of insulation material, a first gate insulation layer GI1, a second gate insulation layer GI2, a first insulation layer IL1, a third gate insulation layer GI3, a second insulation layer IL2, a first planarization layer PLN1, and a second planarization layer PLN2.

The buffer layer BUF may cover the light shielding layer BSM, and the material thereof may include inorganic materials such as silicon nitride and silicon oxide. The buffer layer BUF may be a single layer or a multilayer structure, and the materials of different layers may be different. The first semiconductor layer SE is arranged on the surface of the buffer layer BUF away from the substrate SU.

The first gate insulation layer GI1 covers the first semiconductor layer SE, and the material thereof may include inorganic materials such as silicon nitride and silicon oxide. The first gate layer GA1 is arranged on the surface of the first gate insulation layer GI1 away from the substrate SU.

The second gate insulation layer GI2 covers the first gate layer GA1, and the material thereof may include inorganic materials such as silicon nitride and silicon oxide. The second gate layer GA2 is arranged on the surface of the second gate insulation layer GI2 away from the substrate SU.

The first insulation layer IL1 may cover the second gate layer GA2, and the material thereof may include inorganic materials such as silicon nitride and silicon oxide. The first insulation layer IL1 may be a single layer or a multilayer structure, and the materials of different layers may be different. The second semiconductor layer IG is arranged on the surface of the first insulation layer IL1 away from the substrate SU.

The third gate insulation layer GI3 covers the second semiconductor layer IG, and the material thereof may include inorganic materials such as silicon nitride and silicon oxide. The third gate layer GA3 is arranged on the surface of the third gate insulation layer GI3 away from the substrate SU.

The second insulation layer IL2 may cover the third gate layer GA3, and the material thereof may include inorganic materials such as silicon nitride and silicon oxide. The second insulation layer IL2 may be a single layer or a multilayer structure, and the materials of different layers may be different. The first source and drain layer SD1 is arranged on the surface of the second insulation layer IL2 away from the substrate SU.

The first planarization layer PLN1 may cover the first source and drain layer SD1, and the material thereof may be an organic material such as resin, and planarization may be achieved by leveling the organic material. The second source and drain layer SD2 may be arranged on the surface of the first planarization layer PLN1 away from the substrate SU. In addition, in some embodiments, the first source and drain layer SD1 may be covered with a passivation layer, and the passivation layer may be covered with a first planarization layer PLN1.

The second planarization layer PLN2 may cover the second source and drain layer SD2, and the material thereof may be an organic material such as a resin, and planarization may be achieved by leveling the organic material. The first electrode ANO and the pixel definition layer PDL of the light-emitting device LD may be disposed on the surface of the second planarization layer PLN2 away from the substrate SU.

After considering the specification and practicing the content disclosed herein, it will be easy for a person skilled in the art to think of other embodiments of the present disclosure. The present application is intended to cover any variation, use or adaptation of the present disclosure, which follows the general principles of the present disclosure and includes common knowledge or conventional technical means in the technical field not disclosed in the present disclosure. The description and embodiments are to be regarded as exemplary only, and the true scope and spirit of the present disclosure are indicated by the appended claims.

1. A shift register, comprising:
an input circuit, connected to an input terminal, a first clock signal terminal, and a first input node, and configured to transmit an input signal provided by the input terminal to the first input node in response to a first clock signal provided by the first clock signal terminal;
a voltage stabilization circuit, connected to a first voltage terminal, a first output node, and the first input node, and configured to transmit a first control signal to the first output node under the control of a voltage at the first input node;
a first control circuit, connected to a second voltage terminal, a second clock signal terminal, a third voltage terminal, a second output node, and the first input node, and configured to transmit a second control signal to the second output node under the control of a second clock signal provided by the second clock signal terminal and the voltage at the first input node;
a second control circuit, connected to the third voltage terminal, the first input node, the first output node, and the second output node, and configured to control the first control signal and the second control signal under the control of the voltage at the first input node and the second control signal; and
an output circuit, connected to the first output node, the second output node, the second voltage terminal, the third voltage terminal, and an output terminal, and configured to output a signal at the second voltage terminal or the third voltage terminal from the output terminal under the control of the first control signal and the second control signal, wherein the voltage at the first voltage terminal is capable of enabling conduction between the second voltage terminal and the output terminal.

2. The shift register according to claim 1, wherein the first control circuit comprises:
a first control subcircuit, connected to a second input node, the second voltage terminal, and the second clock signal terminal, and configured to be turned on or off under the control of the second clock signal;
a second control subcircuit, connected to a connection node, the first input node, and the third voltage terminal, and configured to be turned on or off under the control of the voltage at the first input node; and
a third control subcircuit, connected to the second input node and the connection node, and configured to be turned on or off under the control of a voltage at the third voltage terminal.

3. The shift register according to claim 2, wherein
the first control subcircuit comprises a first control transistor, the second control subcircuit comprises a second control transistor, and the third control subcircuit comprises a third control transistor and a first capacitor;
the first control transistor has a gate connected to the second clock signal terminal, a first terminal connected to the second voltage terminal, and a second terminal connected to the second input node;
the second control transistor has a gate connected to the first input node, a first terminal connected to the third voltage terminal, and a second terminal connected to the connection node; and
the third control transistor has a gate connected to the connection node through the first capacitor, a first terminal connected to the connection node, and a second terminal connected to the second input node.

4. The shift register according to claim 1, wherein
the voltage stabilization circuit comprises a voltage stabilization transistor and a second capacitor; and
the voltage stabilization transistor has a gate connected to the first input node and the second capacitor, a first terminal connected to the first voltage terminal, and a second terminal connected to the second capacitor and the first output node.

5. The shift register according to claim 1, wherein
the second control circuit comprises a fourth control subcircuit and a fifth control subcircuit;
the fourth control subcircuit is connected to the third voltage terminal, the first input node, and the second output node, and is configured to control the second control signal under the control of the voltage at the first input node; and
the fifth control subcircuit is connected to the third voltage terminal, the first output node, and the second output node, and is configured to control the first control signal under the control of a voltage at the second output node.

6. The shift register according to claim 5, wherein
the fourth control subcircuit comprises a fourth control transistor, and the fifth control subcircuit comprises a fifth control transistor;
the fourth control transistor has a gate connected to the first input node, a first terminal connected to the third voltage terminal, and a second terminal connected to the second output node; and
the fifth control transistor has a gate connected to the second output node, a first terminal connected to the third voltage terminal, and a second terminal connected to the first output node.

7. The shift register according to claim 1, wherein
the input circuit comprises an input transistor, and the input transistor has a gate connected to the first clock signal terminal, a first terminal connected to the input terminal, and a second terminal connected to the first input node;
the output circuit comprises a first output transistor, a third capacitor, a second output transistor, and a fourth capacitor;
the first output transistor has a gate connected to the first output node, a first terminal connected to the second voltage terminal, and a second terminal connected to the output terminal, and the third capacitor connects the first output node and the second voltage terminal; and
the second output transistor has a gate connected to the second output node, a first terminal connected to the third voltage terminal, and a second terminal connected to the output terminal, and the fourth capacitor connects the second output node and the third voltage terminal.

8. The shift register according to claim 2, wherein the shift register further comprises:
a first isolation circuit connecting the first input node and the voltage stabilization circuit.

9. The shift register according to claim 8, wherein the shift register further comprises:
a second isolation circuit connecting the connection node and the second output node.

10. The shift register according to claim 9, wherein
the first isolation circuit comprises a first isolation transistor, and the second isolation circuit comprises a second isolation transistor;
the first isolation transistor has a gate connected to the second voltage terminal, a first terminal connected to the first input node, and a second terminal connected to the voltage stabilization circuit; and
the second isolation transistor has a gate connected to the second voltage terminal, a first terminal connected to the connection node, and a second terminal connected to the second output node.

11. A driving circuit, comprising a plurality of cascaded shift registers, wherein the shift register comprises:
an input circuit, connected to an input terminal, a first clock signal terminal, and a first input node, and configured to transmit an input signal provided by the input terminal to the first input node in response to a first clock signal provided by the first clock signal terminal;
a voltage stabilization circuit, connected to a first voltage terminal, a first output node, and the first input node, and configured to transmit a first control signal to the first output node under the control of a voltage at the first input node;
a first control circuit, connected to a second voltage terminal, a second clock signal terminal, a third voltage terminal, a second output node, and the first input node, and configured to transmit a second control signal to the second output node under the control of a second clock signal provided by the second clock signal terminal and the voltage at the first input node;
a second control circuit, connected to the third voltage terminal, the first input node, the first output node, and the second output node, and configured to control the first control signal and the second control signal under the control of the voltage at the first input node and the second control signal; and
an output circuit, connected to the first output node, the second output node, the second voltage terminal, the third voltage terminal, and an output terminal, and configured to output a signal at the second voltage terminal or the third voltage terminal from the output terminal under the control of the first control signal and the second control signal, wherein the voltage at the first voltage terminal is capable of enabling conduction between the second voltage terminal and the output terminal.

12. A display panel, comprising:
a driving backplane, comprising a plurality of pixel circuits and first driving circuits, wherein the plurality of pixel circuits are arranged in an array along a row direction and a column direction, and an output terminal of one of the first driving circuits is connected to at least one row of the pixel circuits; and
light-emitting devices, arranged in an array on a side of the driving backplane, wherein
the first driving circuit comprises a plurality of cascaded shift registers, and the shift register comprises:
an input circuit, connected to an input terminal, a first clock signal terminal, and a first input node, and configured to transmit an input signal provided by the input terminal to the first input node in response to a first clock signal provided by the first clock signal terminal;
a voltage stabilization circuit, connected to a first voltage terminal, a first output node, and the first input node, and configured to transmit a first control signal to the first output node under the control of a voltage at the first input node;
a first control circuit, connected to a second voltage terminal, a second clock signal terminal, a third voltage terminal, a second output node, and the first input node, and configured to transmit a second control signal to the second output node under the control of a second clock signal provided by the second clock signal terminal and the voltage at the first input node;
a second control circuit, connected to the third voltage terminal, the first input node, the first output node, and the second output node, and configured to control the first control signal and the second control signal under the control of the voltage at the first input node and the second control signal; and
an output circuit, connected to the first output node, the second output node, the second voltage terminal, the third voltage terminal, and an output terminal, and configured to output a signal at the second voltage terminal or the third voltage terminal from the output terminal under the control of the first control signal and the second control signal, wherein the voltage at the first voltage terminal is capable of enabling conduction between the second voltage terminal and the output terminal.

13. The display panel according to claim 12, wherein
the pixel circuit comprises a plurality of transistors, the number of the first driving circuits is two, and the display panel further comprises a second driving circuit;
in the same pixel circuit, gates of some transistors are connected to the output terminal of the first driving circuit, and gates of some other transistors are connected to an output terminal of the second driving circuit; and
the two first driving circuits are connected to gates of different transistors in the pixel circuit.

14. The display panel according to claim 13, wherein
the pixel circuit comprises a driving transistor, a writing transistor, a compensation transistor, a first reset transistor, a second reset transistor, a first light-emitting control transistor, a second light-emitting control transistor, and a storage capacitor;
the first reset transistor and the compensation transistor are N-type metal oxide transistors, and the driving transistor, the writing transistor, the second reset transistor, the first light-emitting control transistor, and the second light-emitting control transistor are P-type polysilicon transistors;
the first light-emitting control transistor has a first terminal used to receive a first power signal and a second terminal connected to a first terminal of the driving transistor, a second terminal of the driving transistor is connected to a first terminal of the second light-emitting control transistor, and a second terminal of the second light-emitting control transistor is connected to the light-emitting device;
the compensation transistor has a first terminal connected to the second terminal of the driving transistor and a second terminal connected to a gate of the driving transistor;
the first reset transistor has a first terminal used to receive a first reset signal and a second terminal connected to a second terminal of the compensation transistor;
the second reset transistor has a first terminal used to receive a second reset signal and a second terminal connected to the second terminal of the driving transistor;
the writing transistor has a first terminal used to receive a data signal and a second terminal connected to the first terminal of the driving transistor;
the storage capacitor has a first plate connected to the gate of the driving transistor and a second plate used to receive the first power signal;
a gate of the first reset transistor and a gate of the compensation transistor are connected to the output terminal of one of the first driving circuits;
a gate of the first light-emitting control transistor and a gate of the second light-emitting control transistor are connected to the output terminal of the other of the first driving circuits; and
a gate of the writing transistor and a gate of the second reset transistor are connected to the output terminal of the second driving circuit.

15. A driving method for a shift register, wherein the shift register comprises the shift register according to claim 1, and the driving method comprises:
in a first stage, turning on the input circuit and turning off the first control circuit by the first clock signal and the second clock signal, turning on the voltage stabilization circuit, and enabling conduction between the second voltage terminal and the output terminal and disabling conduction between the third voltage terminal and the output terminal under the control of the first control signal;
in a second stage, turning off the input circuit and turning on the first control circuit by the first clock signal and the second clock signal, turning on the voltage stabilization circuit, and enabling conduction between the second voltage terminal and the output terminal and disabling conduction between the third voltage terminal and the output terminal under the control of the voltage at the first voltage terminal, the first control signal, and the second control signal;
in a third stage, turning on the input circuit by the first clock signal and the second clock signal, turning off the voltage stabilization circuit, and enabling conduction between the second voltage terminal and the output terminal and disabling conduction between the third voltage terminal and the output terminal under the control of the voltage at the first voltage terminal, the first control signal, and the second control signal; and
in a fourth stage, turning off the input circuit by the first clock signal and the second clock signal, turning off the voltage stabilization circuit, and disabling conduction between the second voltage terminal and the output terminal and enabling conduction between the third voltage terminal and the output terminal under the control of the voltage at the third voltage terminal, the first control signal, and the second control signal.

16. The driving method according to claim 15, wherein an absolute value of the voltage at the first voltage terminal is greater than an absolute value of a voltage at the second voltage terminal.

17. The driving method according to claim 16, wherein an absolute value of a difference between the absolute value of the voltage at the first voltage terminal and the absolute value of the voltage at the second voltage terminal is 3V.

18. The driving method according to claim 15, wherein a pulse width of the input signal is n times a pulse width of the first clock signal and the second clock signal, where n is a positive integer.

19. The driving circuit according to claim 11, wherein the first control circuit comprises:
a first control subcircuit, connected to a second input node, the second voltage terminal, and the second clock signal terminal, and configured to be turned on or off under the control of the second clock signal;
a second control subcircuit, connected to a connection node, the first input node, and the third voltage terminal, and configured to be turned on or off under the control of the voltage at the first input node; and
a third control subcircuit, connected to the second input node and the connection node, and configured to be turned on or off under the control of a voltage at the third voltage terminal.

20. The driving circuit according to claim 19, wherein
the first control subcircuit comprises a first control transistor, the second control subcircuit comprises a second control transistor, and the third control subcircuit comprises a third control transistor and a first capacitor;
the first control transistor has a gate connected to the second clock signal terminal, a first terminal connected to the second voltage terminal, and a second terminal connected to the second input node;
the second control transistor has a gate connected to the first input node, a first terminal connected to the third voltage terminal, and a second terminal connected to the connection node; and
the third control transistor has a gate connected to the connection node through the first capacitor, a first terminal connected to the connection node, and a second terminal connected to the second input node.
